(19) United States
(12) Patent Application Publication
(10) Pub. No.: US 2019/0139913 A1
(43) Pub. Date: May 9, 2019

(54) ELECTRONIC PACKAGE AND METHOD FOR FABRICATING THE SAME

(71) Applicant: Siliconware Precision Industries Co., Ltd., Taichung City (TW)

(72) Inventors: Bo-Siang Fang, Taichung City (TW); Kuan-Ta Chen, Taichung City (TW); Ying-Wei Lu, Taichung City (TW)

(21) Appl. No.: 15/969,199

(22) Filed: May 2, 2018

(30) Foreign Application Priority Data
Nov. 3, 2017 (TW) 106138120

(51) Int. Cl. H01L 23/66; H01Q 9/04; H01Q 1/38; H01L 23/31; H01L 23/498; H01L 21/56; H01L 21/48

(52) U.S. Cl. CPC H01L 23/66; H01Q 9/0407; H01Q 1/38; H01L 23/3128; H01L 2223/6677; H01L 23/49827; H01L 21/56; H01L 21/4857; H01L 23/49822

(57) ABSTRACT

An electronic package and a method for fabricating the same are provided. The method includes disposing an antenna substrate on a package structure through a plurality of conductive elements. The antenna substrate has an antenna layer and the package structure has an electronic component. As such, an antenna length can be designed according to the requirement of antenna operation, without increasing the area of the package structure.

### BACKGROUND

### 1. Technical Field

The present disclosure relates to electronic packages, and, more particularly, to an electronic package having an antenna structure and a method for fabricating the electronic package.

### 2. Description of Related Art

Along with the rapid development of electronic industries, electronic products are developed toward the trend of multi-function and high performance. Currently, wireless communication technologies have been widely applied in various types of consumer electronic products to facilitate receiving/sending of wireless signals. To meet the miniaturization requirement of consumer electronic products, wireless communication modules are becoming lighter, thinner, shorter and smaller. For example, patch antennas have been widely applied in wireless communication modules of electronic products such as cell phones and personal digital assistants (PDAs) due to their advantages of small size, light weight and easy fabrication.

FIG. 1 is a schematic perspective view of a conventional wireless communication module. Referring to FIG. 1, the wireless communication module 1 has: a substrate 10, a plurality of electronic components 11 disposed on and electrically connected to the substrate 10, an antenna structure 12 formed on the substrate 10, and an encapsulant 13. The substrate 10 is a rectangular circuit board. The antenna structure 12 is of a planar type and has an antenna body 120 and a conductive wire 121 electrically connecting the antenna body 120 and the electronic components 11. The encapsulant 13 encapsulates the electronic components 11 and a portion of the conductive wire 121.

However, as the length of the planar-type antenna structure 12 is increased, the surface area of the substrate 10 for forming the antenna body 120 (i.e., the area where the encapsulant 13 is not formed) needs to be increased accordingly. Since the length and width of the substrate 10 are fixed, it is difficult to further increase the surface area of the substrate 10 for forming the antenna body 120 as well as the length of the antenna structure 12. Hence, it is difficult to meet the requirement of antenna operation.

Therefore, there is a need to provide an electronic package and a fabrication method thereof so as to overcome the above-described drawbacks.

### SUMMARY

In view of the above-described drawbacks, the present disclosure provides an electronic package, which comprises: a package structure comprising a first carrying portion and a second carrying portion stacked on the first carrying portion, wherein at least one electronic component is disposed between the first carrying portion and the second carrying portion; and an antenna substrate disposed on the package structure through a plurality of conductive elements.

The present disclosure provides another electronic package, which comprises: a package structure having at least one electronic component bonded thereto; and an antenna substrate disposed on the package structure through a plurality of conductive elements, wherein the antenna substrate has an insulator made of an encapsulating material.

The present disclosure further provides a method for fabricating an electronic package, which comprises: providing an antenna substrate and a package structure, wherein the package structure comprises a first carrying portion and a second carrying portion stacked on the first carrying portion, and at least one electronic component is disposed between the first carrying portion and the second carrying portion; and disposing the antenna substrate on the package structure through a plurality of conductive elements.

The present disclosure provides another method for fabricating an electronic package, which comprises: providing an antenna substrate and a package structure, wherein the antenna substrate has an insulator made of an encapsulating material; and disposing the antenna substrate on the package structure through a plurality of conductive elements.

In an embodiment, at least one of the first carrying portion and the second carrying portion may have a circuit structure or a substrate structure, and the substrate structure has a core layer or is a coreless substrate structure.

In an embodiment, the first carrying portion may be electrically connected to the second carrying portion.

In an embodiment, the electronic component may be electrically connected to the first carrying portion or the second carrying portion.

In an embodiment, the package structure may be fabricated by disposing the electronic component on the first carrying portion; forming on the first carrying portion an encapsulant that encapsulates the electronic component; and forming the second carrying portion on the encapsulant.

In an embodiment, the antenna substrate may comprise a substrate body having a first antenna layer. In another embodiment, the first antenna layer is formed on a dielectric material and has a plurality of conductive pads and grounding portions, and the first antenna layer is bonded to the conductive elements through the conductive pads.

In an embodiment, the antenna substrate may further comprise an extending portion disposed on the substrate body and having a second antenna layer. In another embodiment, the extending portion may further have an insulator bonded to the second antenna layer. In yet another embodiment, the second antenna layer and the substrate body are positioned on two opposite sides of the insulator. In further another embodiment, the insulator of the extending portion is made of a dielectric material or an encapsulating material.

According to the present disclosure, the antenna substrate is disposed on the package structure through the plurality of conductive elements. As such, the first antenna layer may be arranged on the substrate body of the antenna substrate according to the practical requirement without increasing the surface area of the first carrying portion or the second carrying portion of the package structure. Therefore, even if the size of the first carrying portion or the second carrying portion is predetermined, the length of the first antenna layer of the antenna substrate may be designed to meet the requirements of antenna operation and miniaturization of the electronic package. Further, the second antenna layer may be fabricated on the extending portion to increase the bandwidth according to the practical need.

### BRIEF DESCRIPTION OF DRAWINGS

FIG. 1 is a schematic perspective view of a conventional wireless communication module;

FIGS. 2A to 2F are schematic cross-sectional views showing a method for fabricating an electronic package according to a first embodiment of the present disclosure;

FIG. 3 is a schematic cross-sectional view showing an electronic package according to a second embodiment of the present disclosure;

FIGS. 4A to 4B are schematic cross-sectional views showing a fabrication process of an antenna substrate of FIG. 2E; and

FIGS. 5A to 5C are schematic cross-sectional views showing a fabrication process of an antenna substrate of FIG. 3.

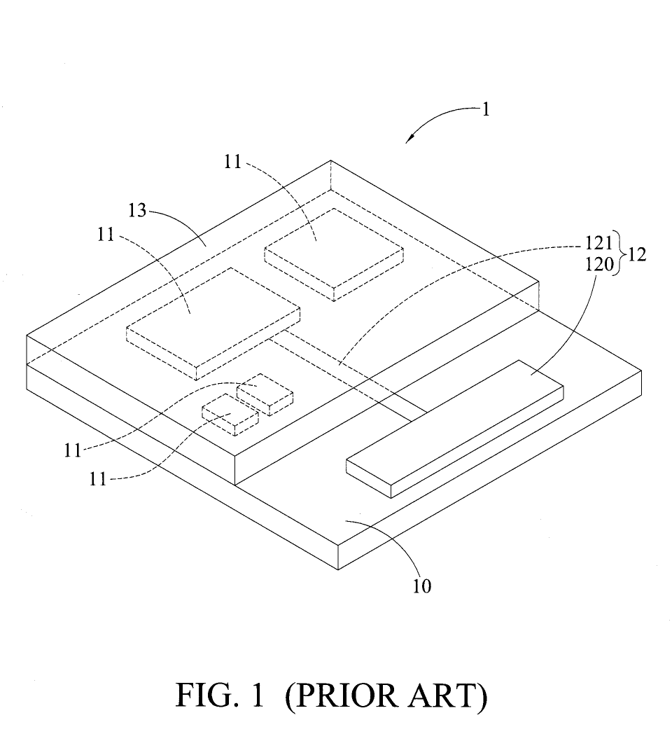

### DETAILED DESCRIPTION OF EMBODIMENTS

The following illustrative embodiments are provided to illustrate the disclosure of the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first”, “second”, “on”, “a” etc. are merely for illustrative purposes and should not be construed to limit the scope of the present disclosure.

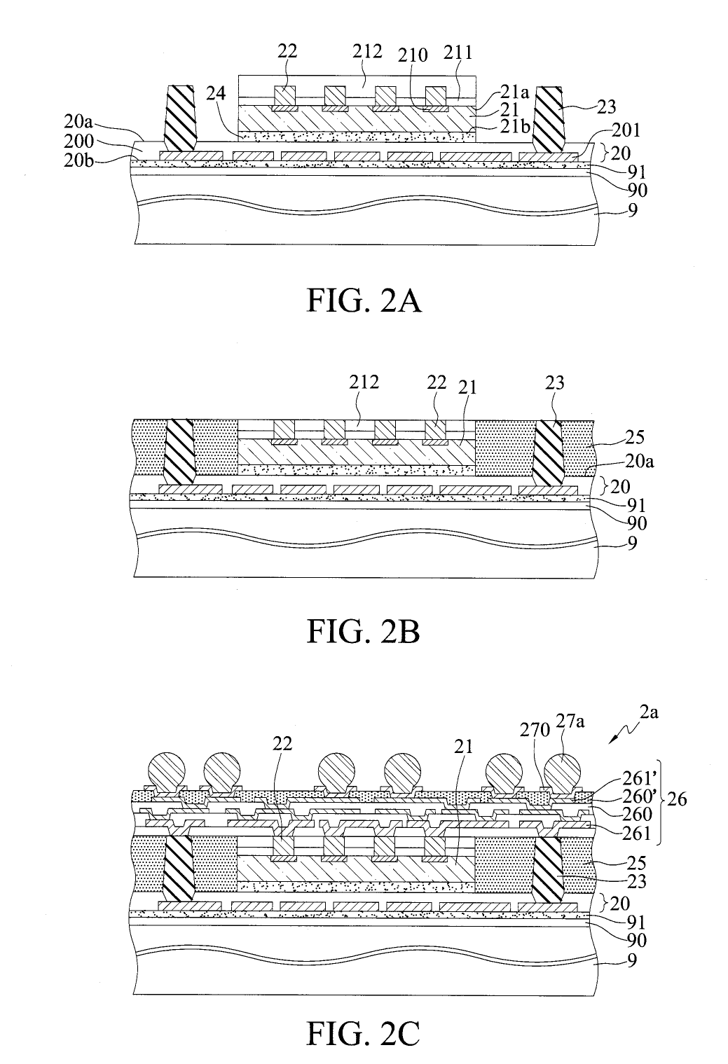

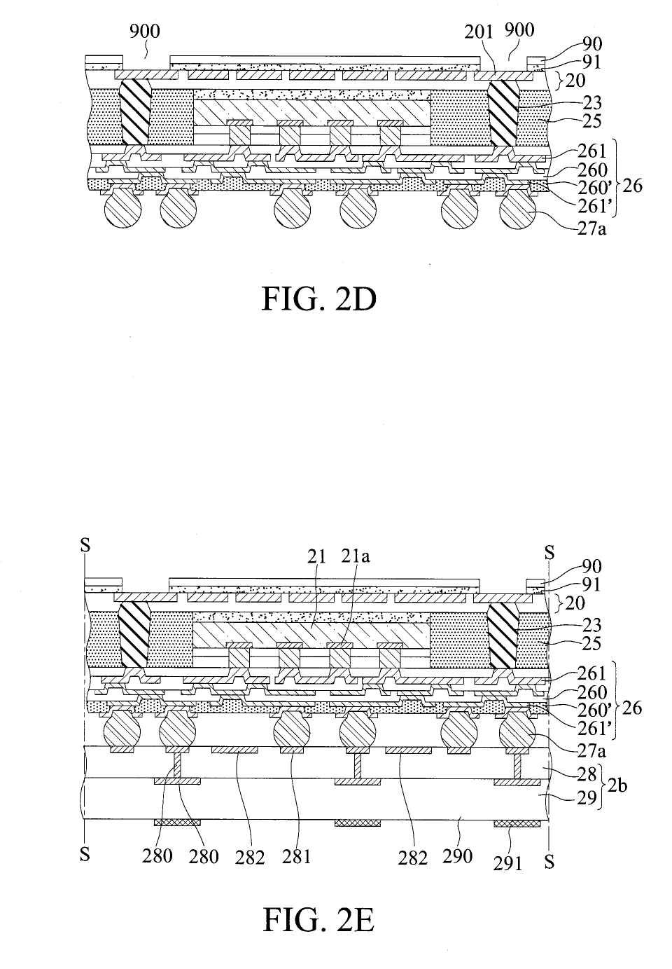

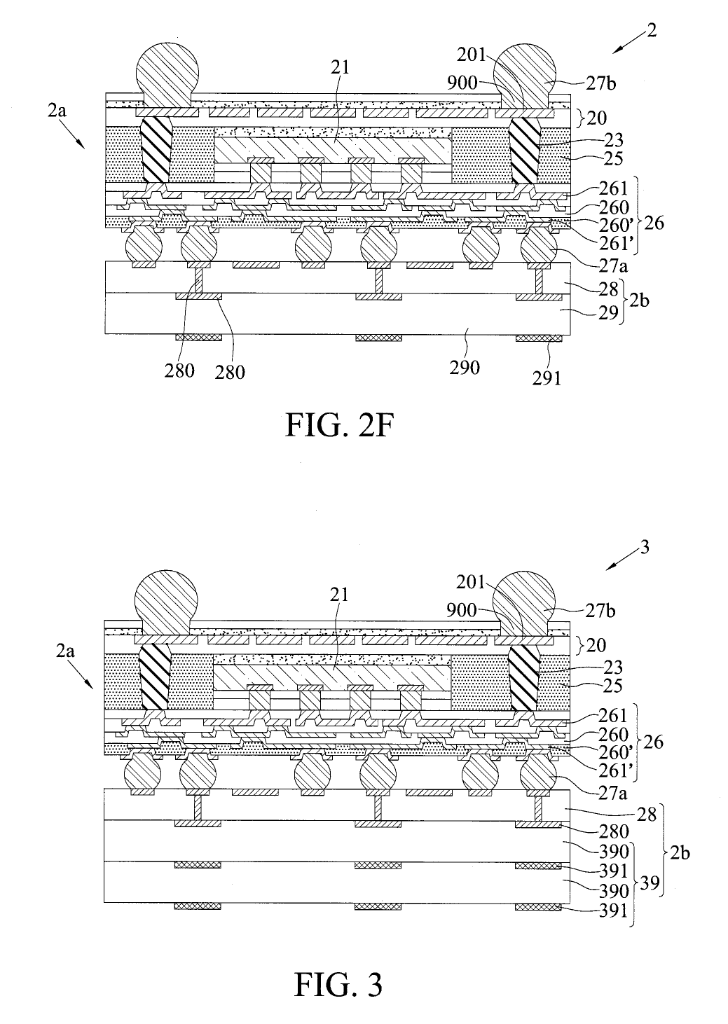

FIGS. 2A to 2F are schematic cross-sectional views showing a method for fabricating an electronic package 2 according to a first embodiment of the present disclosure.

Referring to FIG. 2A, a carrier 9 and a first carrying portion 20 having opposite first and second sides 20a, 20b are provided. The first carrying portion 20 is bonded to the carrier 9 through the second side 20b thereof. A plurality of conductive elements 23 are disposed on the first side 20a of the first carrying portion 20 and electrically connected to the first carrying portion 20, and at least one electronic component 21 is disposed on the first side 20a of the first carrying portion 20.

In an embodiment, the first carrying portion 20 has a circuit structure or a substrate structure, and the substrate structure has a core layer, or is a coreless substrate structure. For example, the first carrying portion 20 is a packaging substrate having a core layer and a circuit structure, or a coreless circuit substrate. The first carrying portion 20 has at least a first insulating layer 200 and a first circuit layer 201, such as a redistribution layer (RDL) formed on the first insulating layer 200. For example, the first circuit layer 201 is made of copper, and the first insulating layer 200 is made of a dielectric material, such as polybenzoxazole (PB 0), polyimide or prepreg. Further, the first carrying portion 20 can be a carrying unit for carrying an electronic component, such as a chip. In an embodiment, the first carrying portion 20 is a lead frame or a silicon interposer.

The carrier 9 is a circular board made of a semiconductor material, such as silicon or glass. A release layer 90 and an adhesive layer 91 are sequentially formed on the carrier 9 by coating and the first carrying portion 20 is disposed on the adhesive layer 91.

Each of the conductive elements 23 has, for example, a post shape or a ball shape. The conductive elements 23 are formed on and electrically connected to the first circuit layer 201. The conductive elements 23 are made of a metal material, such as copper and gold, or a solder material. In an embodiment, the conductive elements 23 can be passive elements.

The electronic component 21 is an active element, such as a semiconductor chip, a passive element, such as a resistor, a capacitor or an inductor, or a combination thereof. In an embodiment, the electronic component 21 is a semiconductor chip having an active surface 21a with a plurality of electrode pads 210 and an inactive surface 21b opposite to the active surface 21a. The inactive surface 21b of the electronic component 21 is attached to the first side 20a of the first carrying portion 20 through a die attachment layer 24.

Further, a plurality of conductive bumps 22 are formed on the electrode pads 210, and protection films 211, 212 are formed on the active surface 21a of the electronic component 21 and cover the electrode pads 210 and the conductive bumps 22. In an embodiment, the protection film 211, 212 are made of PBO, and the conductive bumps 22 are conductive wires, solder balls, copper posts, solder bumps, or studs formed by a wire bonder.

Referring to FIG. 2B, an encapsulant 25 is formed on the first side 20a of the first carrying portion 20 and encapsulates the electronic component 21 and the conductive elements 23. During a planarization process, the protection film 212 and end surfaces of the conductive elements 23 and the conductive bumps 22 are exposed from and flush with an upper surface of the encapsulant 25.

In an embodiment, the encapsulant 25 is made of an insulating material, such as polyimide, a dry film, an epoxy resin or a molding compound. The encapsulant 25 is formed on the first side 20a of the first carrying portion 20 through a lamination or molding process.

The planarization process is a grinding process, through which portions of the conductive elements 23, the protection film 212, the conductive bumps 22 and the encapsulant 25 are removed to allow the protection film 212 and the end surfaces of the conductive elements 23 and the conductive bumps 22 to be flush with the upper surface of the encapsulant 25.

Referring to FIG. 2C, a second carrying portion 26 is formed on the encapsulant 25 and stacked on the first carrying portion 20 so as to form a package structure 2a. The second carrying portion 26 is electrically connected to the conductive elements 23 and the conductive bumps 22 on the electronic component 21.

In an embodiment, the second carrying portion 26 has a circuit structure or a substrate structure, and the substrate structure has a core layer, or is a coreless substrate structure. In an embodiment, the second carrying portion 26 is a packaging substrate having a core layer and a circuit structure, or a coreless circuit substrate. The second carrying portion 26 has a plurality of second insulating layers 260, 260′ and a plurality of second circuit layers 261, 261′, such as redistribution layers formed on the second insulating layers 260, 260′. The outermost one of the second insulating layers 260′ serves as a solder mask layer and the outermost one of the second circuit layers 261′ is exposed from the solder mask layer. Alternatively, the second carrying portion 26 can have a single second insulating layer 260 and a single second circuit layer 261.

Further, the second circuit layers 261, 261′ are made of copper, and the second insulating layers 260, 260′ are made of a dielectric material, such as polybenzoxazole (PBO), polyimide or prepreg.

Furthermore, a plurality of conductive elements 27a, such as solder balls, are formed on the outermost second circuit layer 261′. In an embodiment, a UBM (under bump metallurgy) layer 270 can be pre-formed on the outermost second circuit layer 261′ to facilitate bonding of the conductive elements 27a.

In an embodiment, the second carrying portion 26 can be a carrying unit for carrying an electronic component, such as a chip. In another embodiment, the second carrying portion 26 is a lead frame or a silicon interposer.

Referring to FIG. 2D, the carrier 9 is removed and the overall structure is turned upside down. A plurality of openings 900 are formed in the release layer 90 and the adhesive layer 91 to expose portions of the first circuit layer 201.

In another embodiment, the release layer 90 and the adhesive layer 91 are removed, an insulating layer, such as a solder mask layer, is formed on the second side 20b of the first carrying portion 20, and a plurality of openings are formed in the insulating layer to expose portions of the first circuit layer 201.

Referring to FIG. 2E, an antenna substrate 2b is disposed on the second carrying portion 26 of the package structure 2a. The antenna substrate 2b has a substrate body 28 bonded to the second carrying portion 26 and an extending portion 29 bonded to the substrate body 28. As such, the substrate body 28 is positioned between the extending portion 29 and the second carrying portion 26.

In an embodiment, the antenna substrate 26 is of a packaging substrate type. In an embodiment, the substrate body 28 is a packaging substrate having a core layer and a circuit structure, or a coreless circuit structure. Therein, a plurality of first antenna layers 280 are formed on a dielectric material. The first antenna layers 280 have a plurality of conductive pads 281 and grounding portions 282. The first antenna layers 280 are bonded to the conductive elements 27a through the conductive pads 281.

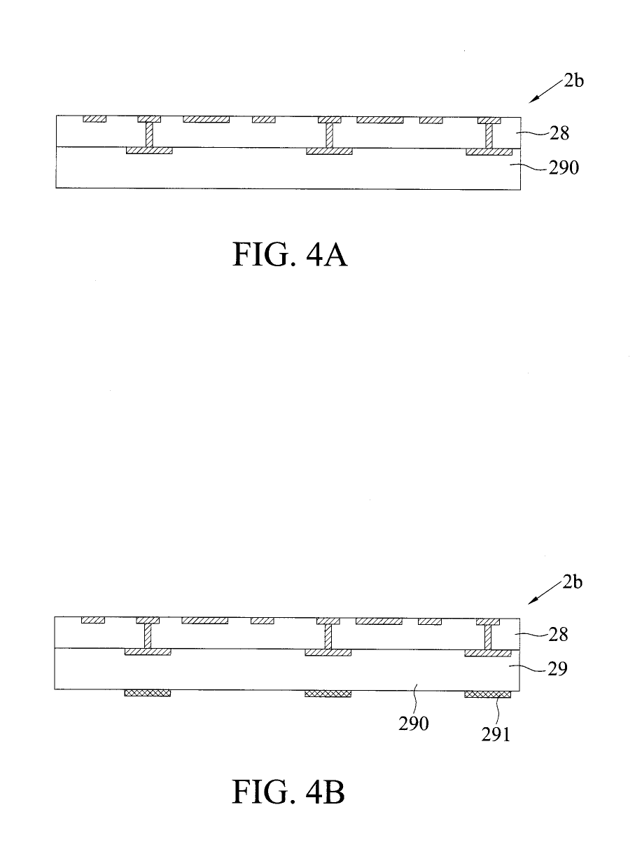

Further, the extending portion 29 has an insulator 290 and a second antenna layer 291 disposed on the insulator 290. The second antenna layer 291 and the first antenna layers 280 are positioned on two opposite sides of the insulator 290. In an embodiment, the insulator 290 of the extending portion 29 is made of an encapsulating material such as BCB, PBO, a dry film or a molding compound. To fabricate the antenna substrate 2b, referring to FIGS. 4A and 4B, the insulator 290 is formed on the substrate body 28 through a molding or lamination process, and then the second antenna layer 291 is formed on the insulator 290.

Further, the active surface 21a of the electronic component 21 faces the antenna substrate 2b. In another embodiment, the inactive surface 21b of the electronic component 21 can face the antenna substrate 2b according to the practical needs. In an embodiment, the active surface 21a of the electronic component 21 is electrically connected to the first carrying portion 20.

Referring to FIG. 2F, a singulation process is performed along cutting paths S of FIG. 2E to obtain an electronic package 2.

In an embodiment, a plurality of conductive elements 27b, such as solder balls, are formed on the first circuit layer 201 in the openings 900. As such, an electronic device, for example, at least one connector or a SiP (system in package) structure, can be mounted on the conductive elements 27b.

Further, according to the process requirement, a non-singulated antenna substrate 2b can be disposed on a wafer-type or strip-type package structure 2a and then a singulation process is performed on the overall structure. In another embodiment, the wafer-type or strip-type package structure 2a is singulated first and then a singulated antenna substrate 2b is disposed on the singulated package structure 2a. In a further embodiment, a singulated antenna substrate 2b is disposed on a wafer-type or strip-type package structure 2a and then the wafer-type or strip-type package structure 2a is singulated. According to the present disclosure, antenna layers are arranged in the antenna substrate 2b so as to eliminate the need to increase the surface area of the first carrying portion 20 or the second carrying portion 26 of the package structure 2a. Therefore, even if the size of the first carrying portion 20 or the second carrying portion 26 is predetermined, the length of the first antenna layers 280 of the substrate body 28 can be designed to meet the requirements of antenna operation and miniaturization of the electronic package 2.

Further, the second antenna layer 291 can be fabricated on the extending portion 29 to increase the bandwidth according to the practical need.

FIG. 3 is a schematic cross-sectional view showing an electronic package 3 according to a second embodiment of the present disclosure. The second embodiment differs from the first embodiment in the fabrication process of the antenna substrate.

Referring to FIG. 3, the antenna substrate 2b has a substrate body 28 and an extending portion 39. The insulator 390 of the extending portion 39 is made of a dielectric material, such as prepreg, polyimide, epoxy resin or glass fiber. The insulator 390 can be formed through a built-up process and the second antenna layer 391 can be formed through an RDL process.

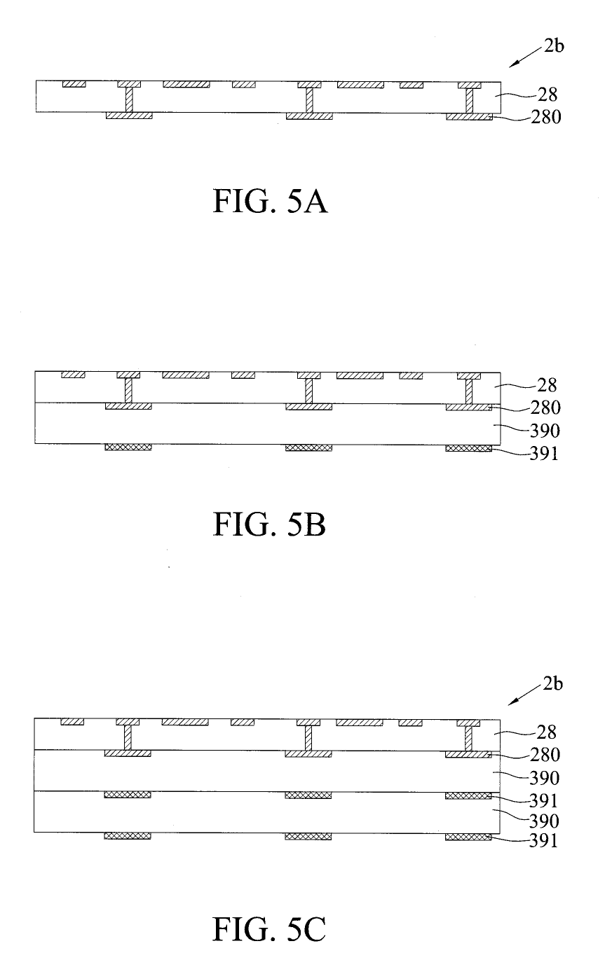

In an embodiment, according to the bandwidth requirement, a plurality of insulators 390 (dielectric layers) and second antenna layers 391 are formed through a built-up process. To fabricate the antenna substrate 2b, referring to FIGS. 5A to 5C, the insulator 390 are formed on the substrate body 28 through a built-up process and the second antenna layers 391 are formed on the insulators 390.

The present disclosure further provides an electronic package 2, 3, which has a package structure 2a and an antenna substrate 2b disposed on the package structure 2a through a plurality of conductive elements.

The package structure 2a has a first carrying portion 20 and a second carrying portion 26 stacked on the first carrying portion 20 through a plurality of conductive elements 23. Further, at least one electronic component 21 is disposed between the first carrying portion 20 and the second carrying portion 26.

The antenna substrate 2b is stacked on the second carrying portion 26 of the package structure 2a. The antenna substrate 2b has a substrate body 28 disposed on the second carrying portion 26 and an extending portion 29, 39 disposed on the substrate body 28.

The extending portion 29, 39 has an insulator 290, 390 and a second antenna layer 291, 391 disposed on the insulator 290, 390. The second antenna layer 291, 391 and the substrate body 28 are positioned on two opposite sides of the insulator 290, 390.

In an embodiment, the first carrying portion 20 is electrically connected to the second carrying portion 26 through a plurality of conductive elements 23.

In an embodiment, the electronic component 21 is electrically connected to the second carrying portion 26. In another embodiment, the electronic component 21 can be electrically connected to the first carrying portion 20.

In an embodiment, the package further has an encapsulant 25 formed between the first carrying portion 20 and the second carrying portion 26 to encapsulate the electronic component 21.

In an embodiment, the substrate body 28 of the antenna substrate 2b is disposed on the second carrying portion 26 of the package structure 2a through a plurality of conductive elements 27a. In another embodiment, the substrate body 28 of the antenna substrate 2b can be disposed on the first carrying portion 20 of the package structure 2a through a plurality of conductive elements 27b.

In an embodiment, the insulator 290, 390 of the extending portion 29, 39 is made of an encapsulating material or a dielectric material.

According to the present disclosure, an antenna substrate is disposed on a package structure through the plurality of conductive elements so as to eliminate the need to increase the surface area of the first carrying portion or the second carrying portion of the package structure. As such, even if the size of the first carrying portion or the second carrying portion is predetermined, the length of the first antenna layer on the substrate body of the antenna substrate can be designed to meet the requirements of antenna operation and miniaturization of the electronic package.

Further, an extending portion can be fabricated on the substrate body of the antenna substrate and a second antenna layer can be formed on the extending portion to increase the bandwidth.

The above-described descriptions of the detailed embodiments are only to illustrate the preferred implementation according to the present disclosure, and it is not to limit the scope of the present disclosure. Accordingly, all modifications and variations completed by those with ordinary skill in the art should fall within the scope of present disclosure defined by the appended claims.

What is claimed is:

1. An electronic package, comprising:
a package structure disposed with at least one electronic component; and
an antenna substrate disposed on the package structure through a plurality of conductive elements.

2. The electronic package of claim 1, wherein the package structure comprises a first carrying portion and a second carrying portion stacked on the first carrying portion, with the at least one electronic component disposed between the first carrying portion and the second carrying portion.

3. The electronic package of claim 2, wherein at least one of the first carrying portion and the second carrying portion has a circuit structure or a substrate structure, and the substrate structure has a core layer or is a coreless substrate structure.

4. The electronic package of claim 2, wherein the first carrying portion is electrically connected to the second carrying portion.

5. The electronic package of claim 2, wherein the electronic component is electrically connected to the first carrying portion or the second carrying portion.

6. The electronic package of claim 2, further comprising an encapsulant formed between the first carrying portion and the second carrying portion and encapsulating the electronic component.

7. The electronic package of claim 1, wherein the antenna substrate comprises a substrate body having a first antenna layer.

8. The electronic package of claim 7, further comprising a dielectric material with the first antenna layer formed thereon, wherein the first antenna layer has a plurality of conductive pads and grounding portions, and is bonded to the conductive elements through the conductive pads.

9. The electronic package of claim 7, wherein the antenna substrate further comprises an extending portion disposed on the substrate body and having a second antenna layer.

10. The electronic package of claim 9, wherein the extending portion further comprises an insulator bonded to the second antenna layer.

11. The electronic package of claim 10, wherein the second antenna layer and the substrate body are positioned on two opposite sides of the insulator.

12. The electronic package of claim 10, wherein the insulator is made of a dielectric material or an encapsulating material.

13. The electronic package of claim 1, wherein the at least one electronic component is bonded to the package structure.

14. A method for fabricating an electronic package, comprising:
providing an antenna substrate and a package structure; and
disposing the antenna substrate on the package structure through a plurality of conductive elements.

15. The method of claim 14, wherein the antenna substrate comprises a first carrying portion and a second carrying portion stacked on the first carrying portion.

16. The method of claim 15, further comprising disposing at least one electronic component between the first carrying portion and the second carrying portion.

17. The method of claim 15, wherein at least one of the first carrying portion and the second carrying portion has a circuit structure or a substrate structure, and the substrate structure has a core layer or is a coreless substrate structure.

18. The method of claim 15, wherein the first carrying portion is electrically connected to the second carrying portion.

19. The method of claim 16, wherein the electronic component is electrically connected to the first carrying portion or the second carrying portion.

20. The method of claim 14, wherein the antenna substrate comprises a substrate body having a first antenna layer.

21. The method of claim 20, further comprising a dielectric material formed with the first antenna layer thereon, wherein the first antenna layer comprises a plurality of conductive pads and grounding portions, and is bonded to the conductive elements through the conductive pads.

22. The method of claim 20, wherein the antenna substrate further comprises an extending portion disposed on the substrate body and having a second antenna layer.

23. The method of claim 22, wherein the extending portion further has an insulator bonded to the second antenna layer.

24. The method of claim 23, wherein the second antenna layer and the substrate body are positioned on two opposite sides of the insulator.

25. The method of claim 23, wherein the insulator is made of a dielectric material or an encapsulating material.

26. The method of claim 22, wherein the extending portion is formed on the substrate body through a molding, lamination or built-up process.

27. The method of claim 16, wherein the package structure is fabricated by:
disposing the electronic component on the first carrying portion;
forming on the first carrying portion an encapsulant encapsulating the electronic component; and
forming the second carrying portion on the encapsulant.
